(19) United States
(12) Patent Application Publication
(10) Pub. No.: US 2026/0071945 A1
(43) Pub. Date: Mar. 12, 2026

(54) Battery Abuse System that Facilitates In-Situ X-Ray Imaging and Multi-Modal Measurements and Methods Thereof

(71) Applicant: Alliance for Sustainable Energy, LLC, Golden, CO (US)

(72) Inventors: Rory Patrick ANDRYKOWSKI, Sedalia, CO (US); Donal Patrick FINEGAN, Lakewood, CO (US); Steven Scott ROBBINS, Arvada, CO (US); Kendal Wayne JOHNSON, Westminster, CO (US)

(21) Appl. No.: 18/826,579

(22) Filed: Sep. 6, 2024

Related U.S. Application Data
(60) Provisional application No. 63/581,329, filed on Sep. 8, 2023.

(51) Int. Cl. G01N 3/44; G01K 13/00; G01N 23/046; G01R 31/385

(52) U.S. Cl. CPC G01N 3/44; G01K 13/00; G01R 31/385; G01N 23/046; G01N 2203/0037; G01N 2223/307; G01N 2223/309; G01N 2223/419

(57) ABSTRACT

Systems and methods that facilitate X-ray imaging of lithium-ion (Li-ion) batteries during mechanical, thermal, and/or electrical abuse are disclosed. In addition to facilitating X-ray imaging, the system also facilitates the simultaneous collection of thermal, electrical, force, and displacement data during the abuse-testing of Li-ion batteries. Materials that are within the field of view of X-ray imaging are highly transparent to X-rays. The system also contains a mechanical indentation apparatus that facilitates high force indentation, compression, or penetration tests of batteries to induce mechanical failure or thermal runaway within the Li-ion battery.

### CROSS-REFERENCE TO RELATED APPLICATIONS

This application claims priority to U.S. Provisional Patent Application No. 63/581,329, filed on Sep. 8, 2023, the contents of which are incorporated herein by reference in their entirety.

### CONTRACTUAL ORIGIN

This invention was made with United States government support under Contract No. DE-AC36-08GO28308 awarded by the U.S. Department of Energy. The United States government has certain rights in this invention.

### BACKGROUND

The lithium-ion (Li-ion) batteries favored for energy storage in electric vehicles, stationary applications, and personal devices are dynamic and systems of perpetually evolving composition and architectures. As Li-ion batteries degrade over time, numerous contributing factors cause unfavorable reactions and morphological transformation. To improve the energy density of batteries, extend their operating life, or make them safer, it is critical to understand how and why such dynamic processes occurs and contribute to the performance and safety of batteries. X-ray diagnostic techniques offer a way to examine properties of Li-ion battery materials, such as their crystal structure, chemical composition, and 3D architectures. However, methods of testing and abusing Li-ion batteries are not able to be performed under an X-ray. Thus, there remains a need for an improved way to X-ray Li-ion batteries.

### SUMMARY

An aspect of the present disclosure is a system for testing a lithium-ion battery in a computerized tomography (CT) scanner, the system including a tray configured to hold the lithium-ion battery, an indenter in contact with the lithium-ion battery, a clamp connected to the indenter configured to press the indenter into the lithium-ion battery, a plurality of gears connected to the clamp and configured to apply a first force to the clamp, a sensor configured to capture a measurement of the lithium-ion battery, and a processor configured to receive the measurement, in which the tray is composed of a material that is substantially transparent to an X-ray beam, and the tray and the indenter are within the X-ray beam of the CT scanner. In some embodiments, the sensor is a load cell, and the measurement is a second force of the indenter on the lithium-ion battery. In some embodiments, the sensor is a distance sensor, and the measurement is a depth of the indenter within the lithium-ion battery. In some embodiments, the sensor is a thermocouple in contact with the lithium-ion battery, and the measurement is a temperature of the lithium-ion battery. In some embodiments, the sensor is a voltage reader, and the measurement is a voltage of the lithium-ion battery. In some embodiments, the plurality of gears includes a worm gear, a worm wheel, and a motor. In some embodiments, the plurality of gears is substantially outside of the X-ray beam. In some embodiments, the system also includes a housing configured to contain the tray, the indenter, the clamp, the plurality of gears, the load cell, the distance sensor, the voltage reader, the thermocouple, and the processor, and a turntable connected to the housing, in which the turntable is configured to rotate the housing. In some embodiments, the material substantially transparent to the X-ray beam is a plastic. In some embodiments, the plastic is at least one of polycarbonate, carbon fiber, polyvinyl chloride, polymethyl methacrylate (PMMA).

An aspect of the present disclosure is a method for testing a lithium-ion battery in a computerized tomography (CT) scanner, the method including holding the lithium-ion battery using a tray, contacting the lithium-ion battery with an indenter, pressing the indenter into the lithium-ion battery using a clamp, applying a first force to the clamp using a plurality of gears, capturing a measurement of the lithium ion battery using a sensor, and receiving the measurement into a processor, in which the tray is composed of a material that is substantially transparent to an X-ray beam, and the tray and the indenter are within the X-ray beam of the CT scanner. In some embodiments, the method also includes containing the tray, the indenter, the clamp, the plurality of gears, the sensor, and the processor in a housing, and rotating the housing using a turntable connected to the housing. In some embodiments, the plurality of gears includes a worm gear, a worm wheel, and a motor. In some embodiments, the plurality of gears is substantially outside of the X-ray beam. In some embodiments, the sensor is a load cell, and the measurement is a second force of the indenter on the lithium-ion battery. In some embodiments, the sensor is a distance sensor, and the measurement is a depth of the indenter within the lithium-ion battery. In some embodiments, the sensor is a thermocouple in contact with the lithium-ion battery, and the measurement is a temperature of the lithium-ion battery. In some embodiments, the sensor is a voltage reader, and the measurement is a voltage of the lithium-ion battery. In some embodiments, the material substantially transparent to the X-ray beam is a plastic. In some embodiments, the plastic is at least one of polycarbonate, carbon fiber, polyvinyl chloride, polymethyl methacrylate (PMMA).

### BRIEF DESCRIPTION OF THE DRAWINGS

Some embodiments of the present disclosure are illustrated in the referenced figures of the drawings. It is intended that the embodiments and figures disclosed herein are to be considered illustrative rather than limiting.

FIGS. 1A-B illustrate (FIG. 1A) a first isometric view and (FIG. 1B) a second isometric view of a lithium-ion (Li-ion) battery abuse system, according to some aspects of the present disclosure.

FIG. 2 illustrates a cross-section view of a Li-ion battery abuse system, according to some aspects of the present disclosure.

FIG. 3 illustrates an isometric view of the internal components of a Li-ion battery abuse system, according to some aspects of the present disclosure.

FIG. 4 illustrates a method for testing a Li-ion battery in a computerized tomography (CT) scanner, according to some aspects of the present disclosure.

FIGS. 5A-B illustrate photographic images of the Li-ion battery abuse system, showing (FIG. 5A) a blunt indenter and (FIG. 5B) a nail indenter, according to some aspects of the present disclosure.

FIGS. 6A-B illustrate (FIG. 6A) a photographic image of a blunt indenter and (FIG. 6B) a slice from an X-ray tomogram of a blunt indenter inserting into a cylindrical Li-ion battery, according to some aspects of the present disclosure.

FIG. 7A-B illustrate (FIG. 7A) a photographic image of a nail indenter and (FIG. 7B) a slice from an X-ray tomogram of a nail indenter inserting into a cylindrical Li-ion battery, according to some aspects of the present disclosure.

FIG. 8 illustrates example data from the Li-ion battery abuse system showing live recordings of distance, force, and battery voltage during an indentation test, according to some aspects of the present disclosure.

### REFERENCE NUMERALS

100 . . . system
105 . . . battery
110 . . . tray
115 . . . indenter
116 . . . needle
120 . . . clamp
121 . . . plurality of gears
125 . . . worm gear
130 . . . worm wheel
135 . . . motor
140 . . . load cell
145 . . . distance sensor
150 . . . voltage reader
155 . . . thermocouple
160 . . . processor
165 . . . beam
170 . . . housing
175 . . . turntable
200 . . . method
205 . . . holding
210 . . . contacting
215 . . . pressing
220 . . . applying
225 . . . capturing
230 . . . receiving
235 . . . containing
240 . . . rotating

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

Among other things, the present disclosure relates to systems and methods that facilitate X-ray imaging of lithium-ion (Li-ion) batteries during mechanical, thermal, and/or electrical abuse. In addition to facilitating X-ray imaging, the Li-ion battery abuse system also facilitates the simultaneous collection of thermal, electrical, force, and displacement data during the abuse-testing of Li-ion batteries. Materials that are within the field of view of X-ray imaging are highly transparent to X-rays, thus maximizing the signal-to-noise ratio for X-ray imaging of Li-ion batteries. The system of the present disclosure also contains a mechanical indentation apparatus that facilitates high force indentation, compression, or penetration tests of batteries to induce mechanical failure or thermal runaway within the Li-ion battery.

In some embodiments, the Li-ion battery abuse system contains a processor to record measurements including temperature, force, displacement, and/or voltage taken by various sensors. The Li-ion battery abuse system may be compatible with rotational stages (i.e., turntables) used in X-ray computed tomography systems, including those found in commercial lab-based products and synchrotron facilities. The Li-ion battery abuse system may be compatible with multiple formats of Li-ion batteries, including pouch, prismatic, and cylindrical. The Li-ion battery abuse system described here may include compact packaging of all electronics and mechanical hardware into a substantially rotationally compatible design, and by using materials that are highly X-ray transparent in the field of view of the X-ray beam. The Li-ion battery abuse system also may facilitate multi-modal measurements, allowing correlation between externally measured temperature, voltage, force, and/or displacement data with internal phenomena recorded via X-ray imaging. This may enable researchers and engineers to X-ray image their battery designs in commercial lab-based X-ray systems as well as synchrotron X-ray systems during abuse testing, allowing a new level of understanding of failure mechanisms.

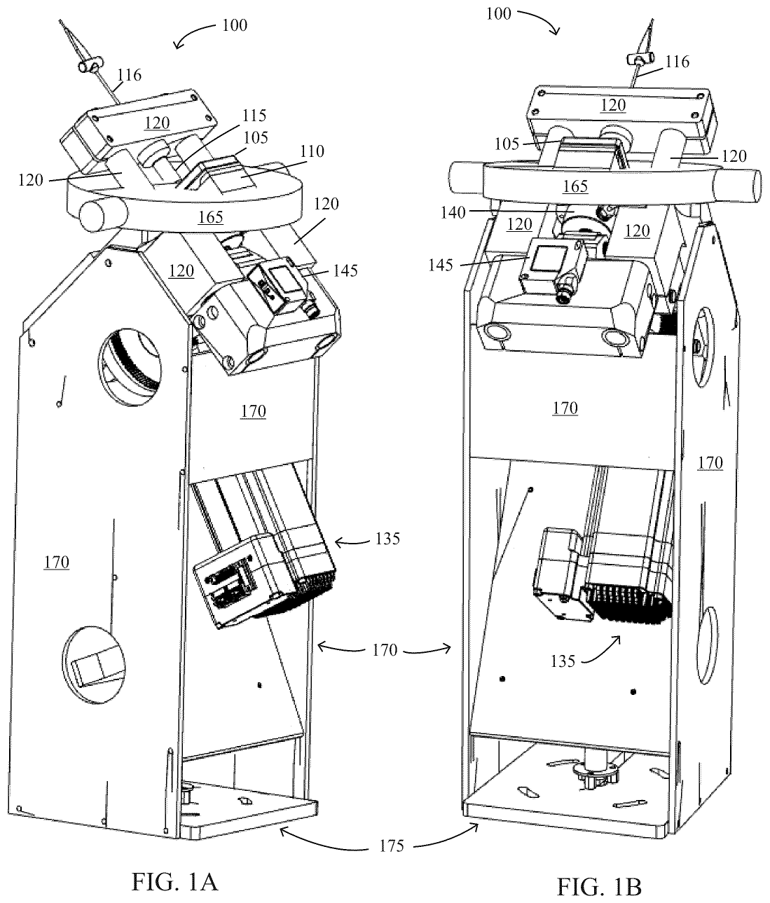

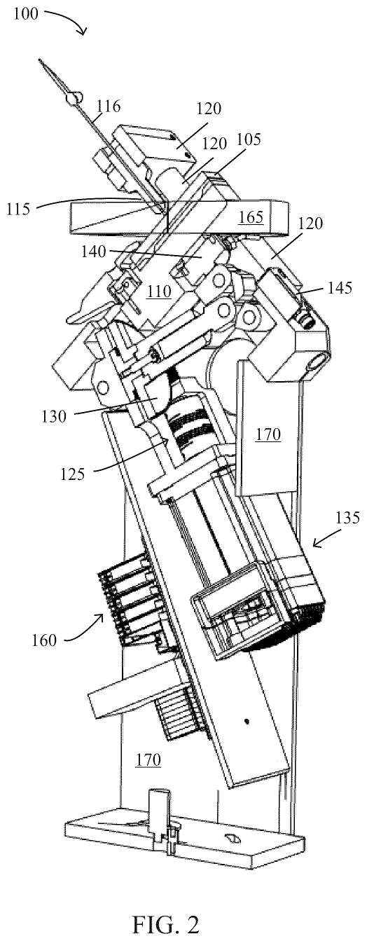

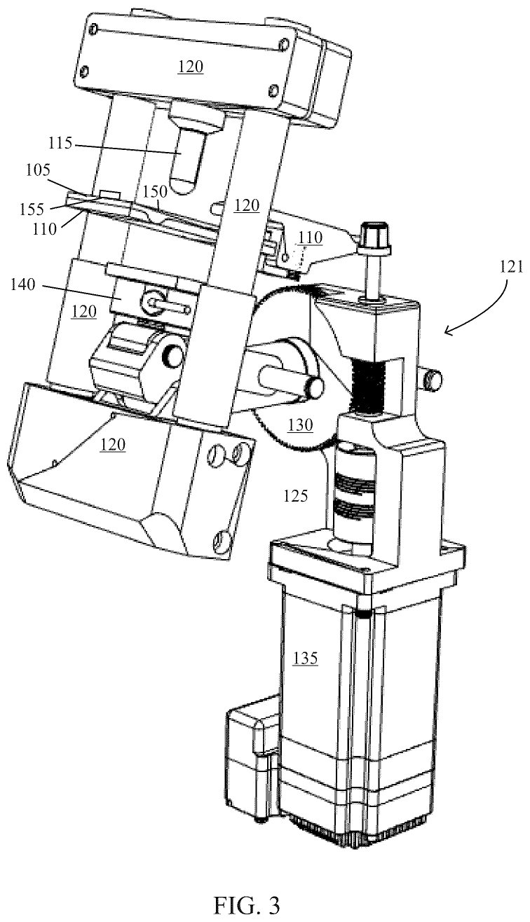

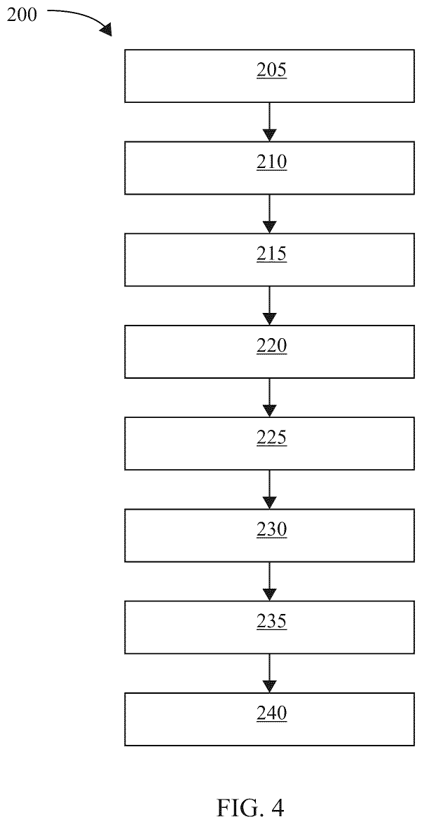

FIGS. 1A-B illustrate (FIG. 1A) a first isometric view and (FIG. 1B) a second isometric view of a lithium-ion (Li-ion) battery abuse system 100, FIG. 2 illustrates a cross-section view of a Li-ion battery abuse system 100, and FIG. 3 illustrates an isometric view of the internal components of a Li-ion battery abuse system 100, according to some aspects of the present disclosure. FIG. 4 illustrates a method 200 for testing a Li-ion battery 105 in a computerized tomography (CT) scanner, according to some aspects of the present disclosure. The method 200 includes holding 205 the Li-ion battery 105 using the tray 110. The method 200 includes contacting 210 the battery 105 with an indenter 115. The method 200 includes pressing 215 the indenter 115 into the battery 105 using the clamp 120. The method 200 includes applying 220 a first force to the clamp 120 using a plurality of gears 121. The method 200 includes capturing 225 a measurement of the battery 105 using a sensor. The method 200 includes receiving 230 the measurement into a processor 160. In some embodiments, the method 200 also includes containing 235 the tray 110, the indenter 115, the clamp 120, the plurality of gears 121, the sensor, and the processor 160 in a housing 170 and rotating 240 the housing 170 using a turntable 175 connected to the housing 170. In some embodiments, the method 200 includes capturing an X-ray image of the battery 105 using the CT scanner.

In some embodiments, the system 100 includes a tray 110 for securing (i.e., holding 205) the battery 105. An indenter 115 may be in contact 210 with the battery 105 in the system 100. The system 100 may also include a clamp 120 configured to press 215 the indenter 115 into the battery 105. A plurality of gears 121 may be connected to the clamp 120 and configured to apply 220 a first force to the clamp 120 (that then can be applied 220 on the battery 105 by the indenter 115) in the system 100. The system 100 may also include a load cell 140 and a distance sensor 145. The load cell 140 may capture 225 a measurement of a second force of the indenter 115 on the battery 105 and the distance sensor 145 may capture 225 a measurement of the depth of the indenter 115 within the battery 105. The system 100 may also include a voltage reader 150 which may capture 225 a measurement of the voltage of the battery 105. The system 100 may also include at least one thermocouple connected to the battery 105 to capture 225 a measurement of the temperature of the battery 105. The system 100 may also include a processor 160 which may receive 230 the measurements taken by the load cell 140, distance sensor 145, voltage reader 150, and at least one thermocouple 155. In some embodiments, all or a majority of the components of the system 100 may be contained 235 within a housing 170. The housing 170 may be connected to a turntable 175, which may rotate 240 the system 100 to allow for X-ray images to be taken at multiple angles, including up to approximately 360°.

In some embodiments, the system 100 includes a housing 170 configured to contain 235 the other components of the system 100. The housing 170 may be made of a substantially solid material, such as a plastic, wood, fiberglass, metal, or glass. The housing may be capable of fitting within a CT scanner device.

In some embodiments, the housing 170 is connected to a turntable 175 which allows the system 100 to rotate 240 up to approximately 360°. This may allow for X-ray images to be taken of the battery 105 from all angles (i.e., from up to approximately 360°). The turntable 175 may be a rotating or revolving tray or other substantially flat surface capable of holding or supporting the housing 170.

The internal components shown in FIG. 3 include a load cell 140, a force multiplying screw drive and gear (i.e., a plurality of gears 121 made up of at least a worm gear 125 and a worm wheel 130), and a rotation motor 135. Other internal components include a laser distance sensor 145 for determining the depth the indenter 115 punctures the battery 105, a worm gear 125 and/or worm wheel 130 or screw (not shown) for force amplification, and a motor 135.

In some embodiments, the plurality of gears 121 are substantially outside of the X-ray beam 165. That is, the plurality of gears 121 are not between the X-ray generator and the battery 105, so their presence does not impact any X-ray images taken. The plurality of gears 121 allow for enough force to be generated for the indenter 115 to damage the battery 105 without impacting the X-ray images. That is, the motor 135 may rotate the worm wheel 130 and/or the worm gear 125, causing a tightening of the clamp 120. As the clamp tightens, the indenter 115 may move closer to the battery 105 and eventually be pressed 215 onto and/or into the battery 105. The rotation of the worm wheel 130 and/or worm gear 125 generates a force which the clamp then applies to the battery 105 to generate abuse. Because the plurality of gears 121 are outside of the X-ray beam, they can be made of metals or other components which may easily generate the necessary force to damage the battery 105. The worm wheel 130 and worm gear 125 may be made of substantially solid materials, such as metal, plastic, or wood. The motor 135 may be powered using electricity to rotate the worm gear 125 and/or worm wheel 130. An exemplary motor 135 may be an indentation motor.

In some embodiments, the tray 110 may be designed to hold 205 or secure the battery 105. That is, the tray 110 may be shaped to the specific type of battery 105 to be tested, whether that's cylindrical, coin, pouch, or other. In some embodiments, the tray 110 may be a clip or other device capable of holding 205 the battery 105. In some embodiments, the tray 110 may be a substantially planar surface on which the battery 105 can be placed. Bands or braces may also be used to hold 205 the battery 105 in position for the testing. The tray 110 may be made of a material that is substantially transparent to an X-ray beam (i.e., a material which will be substantially transparent in an X-ray image). Exemplary such materials include polycarbonate, carbon fiber, polyvinyl chloride (PVC), polymethyl methacrylate (PMMA), or other plastics.

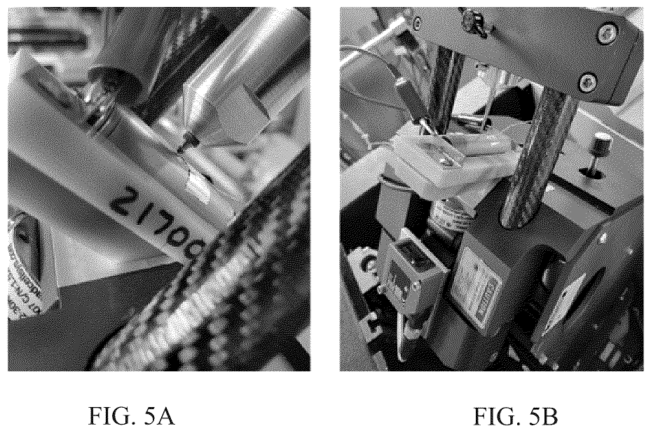

FIGS. 5A-B illustrate photographic images of the Li-ion battery abuse system 100, showing (FIG. 5A) a blunt indenter 115 and (FIG. 5B) a nail indenter 115, according to some aspects of the present disclosure. The battery 105 used in the examples shown in FIGS. 5A-B was a cylindrical battery 105. The indenter 115 may have a blunt end (as shown in FIG. 5A) and/or a sharp end (as shown in FIG. 5B or the needle 116 in FIGS. 1A-B and 2). The shape of the indenter 115 may be selected based on the battery 105 to be tested and the desired abuse or damage to be inflicted on the battery 105.

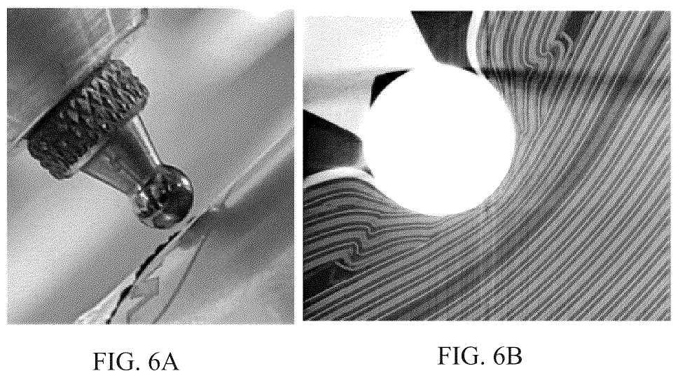

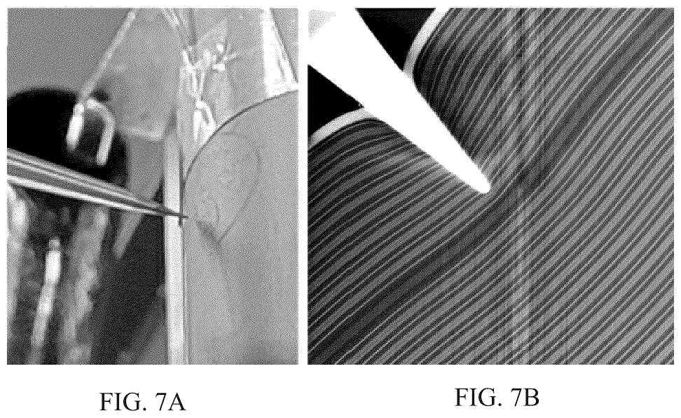

FIGS. 6A-B illustrate (FIG. 6A) a photographic image of a blunt indenter 115 and (FIG. 6B) a slice from an X-ray tomogram of a blunt indenter 115 inserting (i.e., contacting) into a cylindrical Li-ion battery 105, according to some aspects of the present disclosure. FIG. 7A-B illustrate (FIG. 7A) a photographic image of a nail indenter 115 and (FIG. 7B) a slice from an X-ray tomogram of a nail indenter 115 inserting (i.e., contacting) into a cylindrical Li-ion battery 105, according to some aspects of the present disclosure. As shown in FIGS. 6A-B and 7A-B, the force generated by the plurality of gears 121 and conveyed to the clamp 120 and then the indenter 115 is sufficient to puncture a battery 105 through its steel enclosure casing.

In some embodiments, the clamp 120 may be a fastening device used to hold the indenter 115 and the battery 105 tightly together by applying 220 an inward pressing 215. The clamp 120 may be made of any material capable of withstanding the necessary force, such as wood, plastic, aluminum, steel, or other substantially solid materials.

In some embodiments, the system 100 includes at least one sensor, such as a load cell 140, distance sensor 145, voltage reader 150, and/or a thermocouple 155. A sensor may take (i.e., capture 225) a measurement and send it (i.e., communicate) to the processor 160. The sensor(s) may communicate with the processor 160 using an ethernet connection scheme, Modbus TCP protocols, or other electronic communication protocols/strategies. The communication interfaces used by the sensors to send the measurements to the processor 160 can comprise any type of wired or wireless interface as known in the art for communicating via a wired or wireless LAN and/or WAN. The communication interfaces may enable the processor 160 to receive 230 measurements from the sensors.

In some embodiments, a load cell 140 may be a device which converts a force, such as tension, pressure, or torque into a signal (electrical, pneumatic, or mechanical) that can be measured. That is, a load cell is a force transducer. In some embodiments, the load cell 140 may be used to measure and/or approximately a force, tension, pressure, or torque exerted by the indenter 115 on the Li-ion battery 105. A load cell 140 may be an exemplary sensor in the Li-ion abuse system 100, capable of capturing 225 a measurement (i.e., a force, tension, pressure, or torque) and sending the measurement to the processor 160. An exemplary load cell 140 may be a 30KN load cell combined with a load cell amplifier/transmitter.

In some embodiments, a distance sensor 145 may be a laser distance sensor 145 capable of using a laser beam to determine the distance between two objects, or from an object to the distance sensor 145. In some embodiments, a distance sensor 145 may be used to measure a distance traveled (i.e., moved) by the indenter 115 during the testing. In some embodiments, the distance sensor 145 may measure (i.e., capture 225) the distance the indenter 115 punctures or enters the battery 105. An exemplary distance sensor 145 may be an OPT short range (CMOS) photoelectric sensor.

In some embodiments, a voltage reader 150 may be used to measure the voltage of the battery 105 during the testing. The voltage reader 150 may be electrically connected to the battery 105. In some embodiments, if a battery 105 that is within a small electronic device (such as a smart phone) is tested, the voltage reader 150 may be the battery 105 itself. The voltage reader 150 may collect (i.e., capture 225) a voltage measurement and send the voltage measurement to the processor 160.

In some embodiments, the system 100 may include at least one thermocouple 155 connected to the battery 105 and configured to measure a temperature. Depending on the size and type of battery 105 to be tested, various numbers of thermocouples 155 in various locations may be used. Each thermocouple 155 may take (i.e., capture 225) a measurement of the temperature of the battery 105 and send it to the processor 160.

In some embodiments, the processor 160 may correspond to one or many computer processing devices capable of receiving data. For example, the processor 160 may be provided as silicon, as a Field Programmable Gate Array (FPGA), an Application-Specific Integrated Circuit (ASIC), any other type of Integrated Circuit (IC) chip, a collection of IC chips, or the like. As a more specific example, the processor 160 may be provided as a microprocessor, Central Processing Unit (CPU), or plurality of microprocessors that are configured to execute the instructions sets stored in a memory.

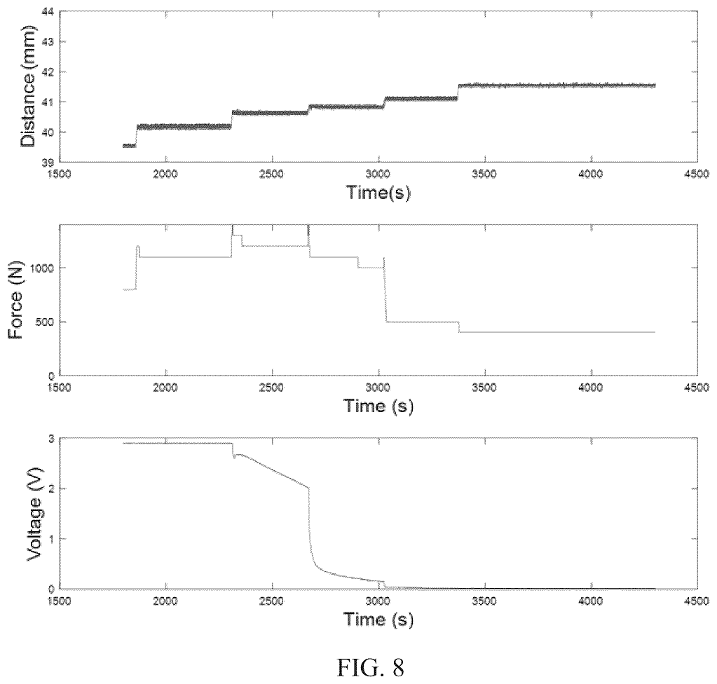

FIG. 8 illustrates example data from the Li-ion battery abuse system 100 showing live recordings of distance, force, and battery voltage during an indentation test, according to some aspects of the present disclosure. The measurements shown in FIG. 8 as collected by a processor 165 shows corresponding changes in displacement distance, force, and cell voltage during a single test. That is, as the plurality of gears 121 conveys a force via the clamp 120 to the indenter 115, the distance the indenter 115 moves is measured by the distance sensor 145 and shown in the top panel of FIG. 8. Synonymously, the force applied by the indenter 115 may be measured by a load cell 140, as shown in the middle panel of FIG. 8. Then, the voltage of the battery 105 may be measured by a voltage reader 150, as shown in the bottom panel of FIG. 8. In the example shown in FIG. 8, it can be seen that as the distance the indenter 115 moved was relatively consistent per time step, but the force applied (i.e., the force felt by the battery 105) varied with time. The voltage of the battery 105 responded to the force until the battery 105 short circuited (i.e., when the battery 105 would fail as a result of mechanical abuse).

FIG. 8 demonstrates the ability of the system 100 to simultaneously capture 225 multiple measurements using a plurality of sensors (i.e., load cell 140, a distance sensor 145 voltage reader 150, and/or thermocouple 155), take X-ray images of the battery 105, and subject the battery 105 to abuse testing (i.e., physical, thermal, and/or electrochemical damage via the indenter 115).

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A system for testing a lithium-ion battery in a computerized tomography (CT) scanner, the system comprising:
a tray configured to hold the lithium-ion battery;
an indenter in contact with the lithium-ion battery;
a clamp connected to the indenter configured to press the indenter into the lithium-ion battery;
a plurality of gears connected to the clamp and configured to apply a first force to the clamp;
a sensor configured to capture a measurement of the lithium-ion battery; and
a processor configured to receive the measurement, wherein:
the tray comprises a material that is substantially transparent to an X-ray beam, and
the tray and the indenter are within the X-ray beam of the CT scanner.

2. The system of claim 1, further comprising:
a housing configured to contain the tray, the indenter, the clamp, the plurality of gears, the load cell, the distance sensor, the voltage reader, the thermocouple, and the processor; and
a turntable connected to the housing; wherein:
the turntable is configured to rotate the housing.

3. The system of claim 1, wherein:
the sensor comprises a load cell, and
the measurement comprises a second force of the indenter on the lithium-ion battery.

4. The system of claim 1, wherein:
the sensor comprises a distance sensor, and
the measurement comprises a depth of the indenter within the lithium-ion battery.

5. The system of claim 1, wherein:
the sensor comprises a thermocouple in contact with the lithium-ion battery, and
the measurement comprises a temperature of the lithium-ion battery.

6. The system of claim 1, wherein:
the sensor comprises a voltage reader, and
the measurement comprises a voltage of the lithium-ion battery.

7. The system of claim 1, wherein:
the plurality of gears comprises:
a worm gear;
a worm wheel; and
a motor.

8. The system of claim 1, wherein:
the plurality of gears is substantially outside of the X-ray beam.

9. The system of claim 1, wherein:
the material substantially transparent to the X-ray beam comprises a plastic.

10. The system of claim 9, wherein:
the plastic comprises polycarbonate, carbon fiber, polyvinyl chloride, polymethyl methacrylate (PMMA).

11. A method for testing a lithium-ion battery in a computerized tomography (CT) scanner, the method comprising:
holding the lithium-ion battery using a tray;
contacting the lithium-ion battery with an indenter;
pressing the indenter into the lithium-ion battery using a clamp;
applying a first force to the clamp using a plurality of gears;
capturing a measurement of the lithium-ion battery using a sensor; and
receiving the measurement into a processor; wherein:
the tray comprises a material that is substantially transparent to an X-ray beam, and
the tray and the indenter are within the X-ray beam of the CT scanner.

12. The method of claim 11, further comprising:
containing the tray, the indenter, the clamp, the plurality of gears, the sensor, and the processor in a housing; and
rotating the housing using a turntable connected to the housing.

13. The method of claim 11, wherein:
the plurality of gears comprises:
a worm gear;
a worm wheel; and
a motor.

14. The method of claim 11, wherein:
the plurality of gears is substantially outside of the X-ray beam.

15. The method of claim 11, wherein:
the sensor comprises a load cell, and
the measurement comprises a second force of the indenter on the lithium-ion battery.

16. The method of claim 11, wherein:
the sensor comprises a distance sensor, and
the measurement comprises a depth of the indenter within the lithium-ion battery.

17. The method of claim 11, wherein:
the sensor comprises a thermocouple in contact with the lithium-ion battery, and
the measurement comprises a temperature of the lithium-ion battery.

18. The method of claim 11, wherein:
the sensor comprises a voltage reader, and
the measurement comprises a voltage of the lithium-ion battery.

19. The method of claim 11, wherein:
the material substantially transparent to the X-ray beam comprises a plastic.

20. The method of claim 19, wherein:
the plastic comprises polycarbonate, carbon fiber, polyvinyl chloride, polymethyl methacrylate (PMMA).
